(19) United States
(12) Patent Application Publication
(10) Pub. No.: US 2024/0032268 A1
(43) Pub. Date: Jan. 25, 2024

(54) RADIO WAVE ABSORBER AND LAMINATE FOR RADIO WAVE ABSORBER

(71) Applicant: NITTO DENKO CORPORATION, Ibaraki-shi, Osaka (JP)

(72) Inventors: Yosuke Nakanishi, Osaka (JP); Eri Ueda, Osaka (JP); Hironobu Machinaga, Osaka (JP)

(73) Assignee: NITTO DENKO CORPORATION, Ibaraki-shi, Osaka (JP)

(21) Appl. No.: 18/255,131

(22) PCT Filed: Nov. 24, 2021
(86) PCT No.: PCT/JP2021/043068

§ 371 Date: May 31, 2023

(30) Foreign Application Priority Data
Dec. 1, 2020 (JP) 2020-199464

(51) Int. Cl. H05K 9/00

(52) U.S. Cl. CPC H05K 9/0088; H05K 9/0084

(57) ABSTRACT

A radio wave absorber 1a includes a resistive layer 10, a reflector 30, and a dielectric layer 20. The resistive layer 10 includes multilayer carbon nanotubes 11. Moreover, the resistive layer 10 has a specific resistance of 1.5 Ω·cm or less. The reflector 30 reflects a radio wave. The dielectric layer 20 is disposed between the resistive layer and the reflector in a thickness direction of the resistive layer 10.

### TECHNICAL FIELD

The present invention relates to a radio wave absorber and a laminate for a radio wave absorber.

### BACKGROUND ART

Radio wave absorbers including a dielectric layer between a resistive layer and a radio wave reflector have been known.

For example, Patent Literature 1 describes a radio wave absorber including a resistive film, a radio wave reflector, and a dielectric layer. The resistive film includes ultrafine conductive fibers such as carbon nanotubes. The radio wave absorber includes the dielectric layer between the resistive film and the radio wave reflector, and the thickness of the dielectric layer is designed on the basis of a λ/4 radio wave absorber theory.

Patent Literature 2 describes an electromagnetic wave absorbing sheet. The electromagnetic wave absorbing sheet is produced by applying an electromagnetic wave absorbing paint composition (B) to at least one surface of a sheet-shaped substrate (A). The electromagnetic wave absorbing paint composition (B) includes a carbon nanomaterial (a), a resin (b), and a solvent (c). The sheet-shaped substrate (A) can be a dielectric sheet. A structure of a λ/4 electromagnetic wave absorber can be obtained by attaching the electromagnetic wave absorbing sheet to a metallic housing or by attaching the electromagnetic wave absorbing sheet including a reflective layer provided on the other surface of the dielectric sheet to a plastic housing. The carbon nanomaterial (a) is, for example, an electrically conductive multilayer carbon nanotubes.

### CITATION LIST

### Patent Literature

Patent Literature 1: JP 2005-311330 A

Patent Literature 2: JP 2006-114877 A

### SUMMARY OF INVENTION

### Technical Problem

It is expected that a need for a radio wave absorber usable in various environments will increase as technologies such as communication and automated driving become more sophisticated. For example, radio wave absorbers may be required to have both a high tensile resistance and a high durability in a hot and humid environment. However, neither Patent Literature 1 nor 2 discusses a radio wave absorber including a resistive layer capable of achieving both a high tensile resistance and a high durability in a hot and humid environment.

In view of such circumstances, the present invention provides a radio wave absorber including a resistive layer advantageous in terms of a high tensile resistance and a high durability in a hot and humid environment and a laminate for a radio wave absorber, the laminate including such a resistive layer.

### Solution to Problem

The present invention provides a radio wave absorber including:
a resistive layer including multilayer carbon nanotubes and having a specific resistance of 1.5 Ω·cm or less;
a reflector that reflects a radio wave; and
a dielectric layer disposed between the resistive layer and the reflector in a thickness direction of the resistive layer.

The present invention also provides a laminate for a radio wave absorber, the laminate including:
a resistive layer including multilayer carbon nanotubes and having a specific resistance of 1.5 Ω·cm or less; and
a dielectric layer, wherein
the resistive layer is placed on the dielectric layer.

### Advantageous Effects of Invention

The resistive layers of the radio wave absorber and the laminate for a radio wave absorber are advantageous in terms of a high tensile resistance and a high durability in a hot and humid environment.

### BRIEF DESCRIPTION OF DRAWINGS

FIG. 1 is a cross-sectional view showing an example of a radio wave absorber according to the present invention.

FIG. 2 is a cross-sectional view showing another example of the radio wave absorber according to the present invention.

FIG. 3 is a cross-sectional view showing yet another example of the radio wave absorber according to the present invention.

FIG. 4 is a cross-sectional view showing yet another example of the radio wave absorber according to the present invention.

FIG. 5 is a cross-sectional view showing yet another example of the radio wave absorber according to the present invention.

FIG. 6 is a cross-sectional view showing an example of a laminate for a radio wave absorber according to the present invention.

FIG. 7 is a field emission scanning electron microscope (FE-TEM) image of a cross-section of a resistive layer of a radio wave absorber according to Example 1.

FIG. 8 is an FE-TEM image of a cross-section of a resistive layer of a radio wave absorber according to Example 3.

FIG. 9 is an FE-TEM image of a cross-section of a resistive layer of a radio wave absorber according to Example 5.

### DESCRIPTION OF EMBODIMENTS

Hereinafter, embodiments of the present invention will be described with reference to the drawings. The present invention is not limited to the following embodiments.

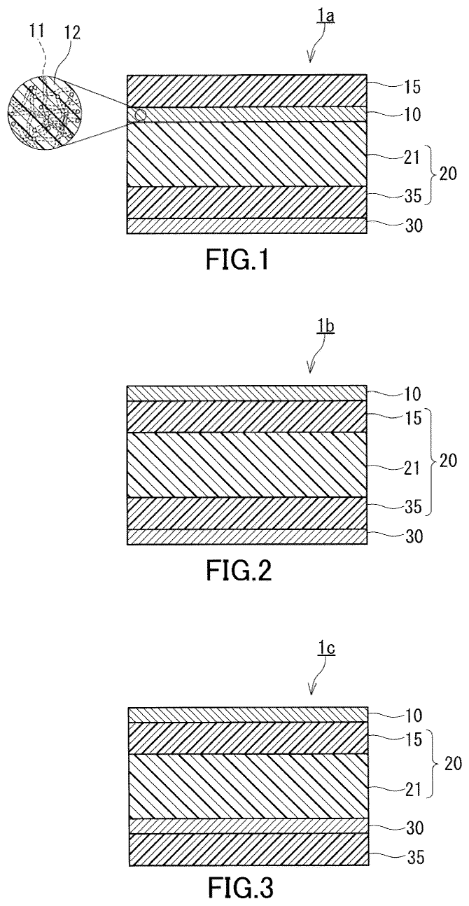

As shown in FIG. 1, a radio wave absorber 1a includes a resistive layer 10, a reflector 30, and a dielectric layer 20. The resistive layer 10 includes multilayer carbon nanotubes 11. Moreover, the resistive layer 10 has a specific resistance of 1.5 Ω·cm or less. The reflector 30 reflects a radio wave. The dielectric layer 20 is disposed between the resistive layer 10 and the reflector 30 in a thickness direction of the resistive layer 10.

The radio wave absorber 1a is, for example, a λ/4 radio wave absorber. The radio wave absorber 1a is designed to cause interference between a radio wave reflected by the surface of the resistive layer 10 (front surface reflection) and a radio wave reflected by the reflector 30 (back surface reflection) upon incidence of a radio wave having a wavelength λ₀ to be absorbed on the radio wave absorber 1a. A radio wave that the radio wave absorber 1a is able to absorb can be, for example, a millimeter or submillimeter wave in a particular frequency range.

The resistive layer 10 has a high tensile resistance because the resistive layer 10 includes the multilayer carbon nanotubes 11 to have a specific resistance of 1.5 Ω·cm or less. For example, properties, such as electrical resistance, of the resistive layer 10 are not likely to vary when the resistive layer 10 is pulled. It is thought that the electrical resistance of the multilayer carbon nanotube 11 itself is not likely to vary while the resistive layer 10 is being pulled. In addition, the high tensile resistance of the resistive layer 10 is thought to be attributable to how the multilayer carbon nanotubes 11 are in contact with each other. The multilayer carbon nanotube 11 has a relatively small diameter (fiber diameter) for a fibrous carbon material. It is thought that because of the relatively small diameters, the multilayer carbon nanotubes 11 are tangled and in line contact with each other in the resistive layer 10. It is thought that because the resistive layer 10 includes the multilayer carbon nanotubes 11 to have a specific resistance of 1.5 Ω·cm or less, the state where the multilayer carbon nanotubes 11 are tangled and in line contact with each other is likely to be maintained when the resistive layer 10 is pulled. It is understood that the resistive layer 10 therefore exhibits a high tensile resistance.

It is conceivable that instead of multilayer carbon nanotubes, another fibrous carbon material such as carbon nanofibers is included in a resistive layer. However, a carbon nanofiber has a fiber diameter (e.g., more than 70 nm) larger than that of a multilayer carbon nanotube, and it is thought that carbon nanofibers are less likely to be tangled on lines in a resistive layer. Therefore, it is likely that carbon nanofibers are in point contact with each other and thus have weak contact with each other. Consequently, it is thought that carbon nanofibers included in a resistive layer are likely to become apart from each other by pulling the resistive layer and that it is difficult to increase the tensile resistance of the resistive layer.

Since the resistive layer 10 includes the multilayer carbon nanotubes 11, the resistive layer 10 is likely to exhibit a high durability in a hot and humid environment. For example, properties, such as electrical resistance, of the resistive layer 10 is not likely to vary when the resistive layer 10 is placed in a hot and humid environment. It is thought that owing to the multilayer structure of the multilayer carbon nanotube 11, even if the outermost layer of the multilayer carbon nanotube 11 chemically deteriorates in a hot and humid environment to impair a bond between carbon atoms, a physical condition of an internal layer thereof is likely to be maintained. Therefore, the multilayer carbon nanotube 11 is likely to maintain its electric conductivity in a hot and humid environment. It is thought that the resistive layer 10 is consequently likely to exhibit a high durability in a hot and humid environment. On the other hand, for example, in the case where single-layer carbon nanotubes are included in a resistive layer instead of multilayer carbon nanotubes, chemical deterioration of surfaces of the single-layer carbon nanotubes in a hot and humid environment can decrease the electric conductivity of the single-layer carbon nanotubes. For example, the chemical deterioration of the surfaces of the single-layer carbon nanotubes in the hot and humid environment can break a conjugated system structure and can decrease the electric conductivity of the resistive layer.

Herein, the term “hot and humid environment” is not limited to a particular environment. A hot and humid environment is, for example, an environment having a temperature of 60° C. to 120° C. and a relative humidity of 60% or more. In one example, a hot and humid environment is an environment having a temperature of 85° C. and a relative humidity of 85%.

The specific resistance of the resistive layer 10 may be 1.4 Ω·cm or less, 1.3 Ω·cm or less, or 1.2 Ω·cm or less. The lower limit of the specific resistance of the resistive layer 10 is not limited to a particular value. The specific resistance of the resistive layer 10 may be 0.001 Ω·cm or more, 0.005 Ω·cm or more, 0.01 Ω·cm or more, or 0.02 Ω·cm or more.

The diameter of the multilayer carbon nanotube 11 is not limited to a particular value. The multilayer carbon nanotube 11 has a diameter of, for example, 70 nm or less. In this case, the multilayer carbon nanotubes 11 are likely to be tangled and in line contact with each other in the resistive layer 10, and the resistive layer 10 is likely to exhibit a high tensile resistance.

The diameter of the multilayer carbon nanotube 11 may be 60 nm or less, 50 nm or less, 40 nm or less, or 30 nm or less. The diameter of the multilayer carbon nanotube 11 may be, for example, 3 nm or more, 5 nm or more, or 7 nm or more. The diameter of the multilayer carbon nanotube 11 can be determined, for example, by observing a specimen for observation of a cross-section of the resistive layer 10 using a field emission scanning electron microscope, the specimen being produced according to micro-sampling using a focused ion beam (FIB) processing system. Alternatively, the diameter of the multilayer carbon nanotube 11 in the resistive layer 10 may be determined according to a technical document, such as a catalog, on a radio wave absorber or its material.

A content of the multilayer carbon nanotubes 11 in the resistive layer 10 is not limited to a particular value as long as the resistive layer 10 has a specific resistance of 1.5 Ω·cm or less. The content of the multilayer carbon nanotubes 11 in the resistive layer 10 is, for example, 3% or more on a mass basis. It is thought that because of this, the state where the multilayer carbon nanotubes 11 are tangled and in line contact with each other is likely to be maintained more reliably even when the resistive layer 10 is pulled. The resistive layer 10 therefore more reliably exhibits a high tensile resistance.

The content of the multilayer carbon nanotubes 11 in the resistive layer may be 5% or more, 10% or more, 20% or more, 30% or more, 40% or more, 50% or more, or 60% or more on a mass basis. The content of the multilayer carbon nanotubes 11 in the resistive layer is, for example, 90% or less on a mass basis, and may be 85% or less, or 80% or less on a mass basis.

As shown in FIG. 1, the resistive layer 10 further includes, for example, a binder 12. The binder 12 binds the multilayer carbon nanotubes 11 to each other. The binder 12 includes, for example, at least one selected from the group consisting of a polyurethane, a polyacrylate, an epoxy resin, and a polyester. It is thought that because of this, the state where the multilayer carbon nanotubes 11 are tangled and in line contact with each other is likely to be maintained more reliably even when the resistive layer 10 is pulled. The resistive layer 10 therefore more reliably exhibits a high tensile resistance.

The resistive layer 10 is, for example, free of an aliphatic cellulose ester. Even when the resistive layer 10 is, as just described, free of an aliphatic cellulose ester, the resistive layer 10 has properties desirable for a resistive layer of a radio wave absorber to have.

A relation between an electrical resistance Rₜ of the resistive layer 10 after a tensile test and an electrical resistance R₀ of the resistive layer 10 before the tensile test is not limited to a particular relation. In the tensile test, for example, a tensile stress is applied to the resistive layer 10 in a direction perpendicular to the thickness direction of the resistive layer 10 to cause a 10% strain. The electrical resistance Rₜ and the electrical resistance R₀ satisfy, for example, a relation 100×{(Rₜ/R₀)−1}≤15. As described above, the resistive layer 10 has a high tensile resistance, and the electrical resistance of the resistive layer 10 is not likely to vary even when the resistive layer 10 is pulled.

For the resistive layer 10, a value of 100×{(Rₜ/R₀)−1} is desirably 10 or less, and more desirably 5 or less.

A relation between a sheet resistance R_{H} of the resistive layer 10 after a hot and humid environment test and a sheet resistance Rᵢ of the resistive layer 10 before the hot and humid environment test is not limited to a particular relation. In the hot and humid environment test, for example, an environment of the resistive layer 10 is maintained at a temperature of 85° C. and a relative humidity of 85% for 24 hours. The sheet resistance R_{H} and the sheet resistance Rᵢ satisfy, for example, a relation 100×{(R_{H}/Rᵢ)−1}≤15. A value of 100×{(R_{H}/Rᵢ)−1} is desirably 10 or less, more desirably 5 or less, and may be 0.05 or less.

A sheet resistance of the resistive layer 10 is not limited to a particular value as long as the radio wave absorber 1a can absorb a desired radio wave. The sheet resistance of the resistive layer 10 is, for example, 200Ω/□ to 600Ω/□. The sheet resistance of the resistive layer 10 may be 220Ω/□ to 550Ω/□, or 240Ω/□ to 500 Ω/□.

The thickness of the resistive layer 10 is not limited to a particular thickness. The thickness of the resistive layer 10 is, for example, 75 μm or less, and may be 60 μm or less, 50 μm or less, or 40 μm or less. The thickness of the resistive layer 10 is, for example, 0.5 μm or more.

The reflector 30 is not limited to a particular one as long as the reflector 30 can reflect a radio wave to be absorbed. The reflector 30 is, for example, in the shape of a layer. In this case, the reflector 30 has a lower sheet resistance than that of the resistive layer 10. The reflector 30 may have a shape other than a layer. For example, a housing, a structural member, or the like of a given device may function as the reflector 30.

The reflector 30 includes, for example, a conductive material such as a metal, an alloy, a metal oxide, or a carbon material. The reflector 30 may include at least one selected from the group consisting of aluminum, copper, iron, an aluminum alloy, a copper alloy, and an iron alloy, or may include a transparent conductive material such as tin-doped indium oxide.

A relative permittivity of the dielectric layer 20 is not limited to a particular value as long as the radio wave absorber 1a can absorb a desired radio wave. The relative permittivity of the dielectric layer 20 is, for example, 2.0 to 20.0. In this case, the thickness of the dielectric layer 20 is easily adjusted, and so is the radio wave absorption performance of the radio wave absorber 1a. The relative permittivity of the dielectric layer 20 is, for example, a relative permittivity measured at 10 GHz by a cavity resonance method.

The dielectric layer 20 is formed of, for example, a given polymer. The dielectric layer 20 includes, for example, at least one polymer selected from the group consisting of ethylene-vinyl acetate copolymer, vinyl chloride resin, urethane resin, acrylic resin, acrylic urethane resin, polyethylene, polypropylene, silicone, polyethylene terephthalate, polyethylene naphthalate, polycarbonate, polyimide, and cycloolefin polymer. In this case, the thickness of the dielectric layer 20 is easily adjusted and the manufacturing cost of the radio wave absorber 1a can be maintained at a low level. The dielectric layer 20 can be produced, for example, by hot-pressing a given resin composition.

The dielectric layer 20 may be formed as a single layer or as a plurality of layers made of the same material or different materials. When the dielectric layer 20 includes n layers (n is an integer of two or greater), the relative permittivity of the dielectric layer 20 is determined, for example, as follows. The relative permittivity εᵢ of each layer is measured (i is an integer of one to n). Next, the relative permittivity εᵢ of each layer is multiplied by the proportion of the thickness tᵢ of the layer in the total thickness T of the dielectric layer 20 to determine εᵢ×(tᵢ/T). The relative permittivity of the dielectric layer 20 can be determined by adding the εᵢ×(tᵢ/T) values of all layers.

As shown in FIG. 1, the dielectric layer 20 includes, for example, a first layer 21 and a second layer 35. The first layer 21 is disposed between the resistive layer 10 and the second layer 35. The first layer 21 includes, for example, at least one polymer selected from the group consisting of ethylene-vinyl acetate copolymer, vinyl chloride resin, urethane resin, acrylic resin, acrylic urethane resin, polyethylene, polypropylene, silicone, polyethylene terephthalate, polyethylene naphthalate, polycarbonate, polyimide, and cycloolefin polymer.

In the radio wave absorber 1a, the second layer 35 supports, for example, the reflector 30 in the shape of a layer. In this case, the layer-shaped reflector 30 is, for example, a metallic foil or an alloy foil. The layer-shaped reflector 30 may be produced, for example, by forming a film on the second layer 35 by a method such as sputtering, ion plating, or coating (such as bar coating). For example, the second layer 35 of the radio wave absorber 1a is disposed closer to the resistive layer 10 than the layer-shaped reflector 30 is, and constitutes a portion of the dielectric layer 20. The second layer 35 includes, for example, an organic polymer. The organic polymer is not limited to a particular polymer, and is, for example, polyethylene terephthalate (PET), polyethylene naphthalate (PEN), acrylic resin (PMMA), polycarbonate (PC), polyimide (PI), or cycloolefin polymer (COP). Among these, PET is desirable as the organic polymer included in the second layer 35 in terms of the balance between good heat-resistance, dimensional stability, and manufacturing cost.

The second layer 35 has a thickness of, for example, 5 to 150 μm and desirably has a thickness of 5 to 100 μm. In this case, the second layer 35 has low flexural rigidity, and occurrence of a wrinkle in the second layer 35 or deformation of the second layer 35 can be reduced during formation of the layer-shaped reflector 30. The second layer 35 may be omitted.

As shown in FIG. 1, the radio wave absorber 1a further includes, for example, a supporting layer 15. The supporting layer 15 includes an organic polymer and supports the resistive layer 10. In this case, the supporting layer 15 protects the resistive layer 10, and the radio wave absorber 1a is likely to exhibit a high durability. Moreover, the supporting layer 15 makes it easy to adjust the thickness of the resistive layer 10 to be uniform.

The organic polymer included in the supporting layer 15 is not limited to a particular polymer, and is, for example, polyethylene terephthalate (PET), polyethylene naphthalate (PEN), acrylic resin (PMMA), polycarbonate (PC), polyimide (PI), or cycloolefin polymer (COP). Among these, PET is desirable as the organic polymer included in the second layer 35 in terms of the balance between good heat-resistance, dimensional stability, and manufacturing cost.

The radio wave absorber 1a may be modified to radio wave absorbers 1b and 1c respectively shown in FIGS. 2 and 3. The radio wave absorbers 1b and 1c are configured in the same manner as the radio wave absorber 1a unless otherwise described. The components of the radio wave absorbers 1b and 1c that correspond to the components of the radio wave absorber 1a are denoted by the same reference characters, and detailed descriptions of such components are omitted. The description given for the radio wave absorber 1a is applicable to the radio wave absorbers 1b and 1c unless there is a technical inconsistency.

In the radio wave absorbers 1b and 1c, the supporting layer 15 is disposed closer to the reflector 30 than the resistive layer 10 is in the thickness direction of the resistive layer 10. In this case, the supporting layer 15 can constitute a portion of the dielectric layer 20.

Moreover, in the radio wave absorber 1c, the layer-shaped reflector 30 is disposed closer to the resistive layer 10 than the second layer 35 is in the thickness direction of the resistive layer 10. In this case, the second layer 35 is likely to protect the layer-shaped reflector 30, and the radio wave absorber 1c is likely to have a high durability.

In the radio wave absorbers 1a to 1c, the first layer 21 may be composed of a plurality of layers. The first layer 21 can be composed of a plurality of layers particularly when the first layer 21 is in contact with at least one of the resistive layer 10 and the layer-shaped reflector 30, as shown in FIGS. 1 and 3.

The first layer 21 may be adhesive or does not need to be adhesive. When the first layer 21 is adhesive, an adhesive layer may be disposed in contact with at least one of the principal surfaces of the first layer 21 or may be disposed in contact with neither of the principal surfaces of the first layer 21. When the first layer 21 is not adhesive, an adhesive layer is desirably disposed in contact with each of the principal surfaces of the first layer 21. In the case where the dielectric layer 20 includes the supporting layer 15, as in the radio wave absorbers 1b and 1c, and the supporting layer 15 is not adhesive, an adhesive layer does not need to be disposed in contact with both of the principal surfaces of the supporting layer 15. In this case, an adhesive layer can be disposed in contact with one principal surface of the supporting layer 15. In the case where the dielectric layer 20 includes the second layer 35, as in the radio wave absorbers 1a and 1b, and the second layer 35 is not adhesive, an adhesive layer does not need to be disposed in contact with both of the principal surfaces of the second layer 35. An adhesive layer can be disposed in contact with at least one principal surface of the second layer 35.

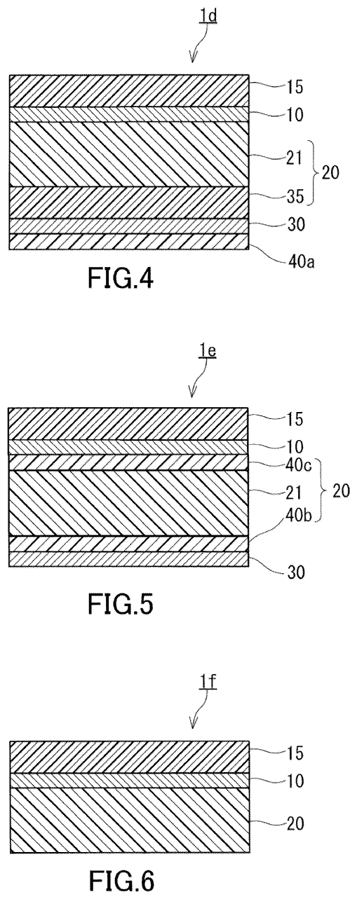

The radio wave absorber 1a may be modified to radio wave absorbers 1d and 1e respectively shown in FIGS. 4 and 5. The radio wave absorbers 1d and 1e are configured in the same manner as the radio wave absorber 1a unless otherwise described. The components of the radio wave absorbers 1d and 1e that are the same as or correspond to the components of the radio wave absorber 1a are denoted by the same reference characters, and detailed descriptions of such components are omitted. The description given for the radio wave absorber 1a is applicable to the radio wave absorbers 1d and 1e unless there is a technical inconsistency.

As shown in FIG. 4, the radio wave absorber 1d further includes an adhesive layer 40a. In the radio wave absorber 1d, the reflector 30 is disposed between the dielectric layer 20 and the adhesive layer 40a in the thickness direction of the resistive layer 10. The adhesive layer 40a may be in contact with or apart from the reflector 30 in a thickness direction of the adhesive layer 40a. For example, an additional layer such as a supporting layer supporting the reflector 30 may be disposed between the adhesive layer 40a and the reflector 30 in the thickness direction of the adhesive layer 40a. In this case, a component included in the adhesive layer 40a is less likely to be in contact with the reflector 30, and the reflector 30 is less likely to be deteriorated.

For example, the radio wave absorber 1d can be attached to a given article by bringing the adhesive layer 40a into contact with the article and pressing the radio wave absorber 1d to the article. A radio wave absorber-attached article can be obtained in this manner.

The adhesive layer 40a includes, for example, a rubber adhesive, an acrylic adhesive, a silicone adhesive, or a urethane adhesive. The radio wave absorber 1d may further include a release liner (not illustrated). In this case, the release liner covers the adhesive layer 40a. The release liner is typically a film capable of maintaining the adhesiveness of the adhesive layer 40a while covering the adhesive layer 40a, the film being easily removable from the adhesive layer 40a. The release liner is, for example, a film made of a polyester resin such as PET. Removal of the release liner exposes the adhesive layer 40a and makes it possible to attach the radio wave absorber 1d to an article.

In the radio wave absorber, the dielectric layer 20 may be adhesive to the reflector 30. For example, as shown in FIG. 5, the dielectric layer 20 of the radio wave absorber 1a has a plurality of layers including an adhesive layer 40b. The adhesive layer 40b is in contact with the reflector 30. The adhesive layer 40b includes, for example, a rubber adhesive, an acrylic adhesive, a silicone adhesive, or a urethane adhesive. The adhesive layer 40b is disposed, for example, between the first layer 21 and the reflector 30 in the thickness direction of the resistive layer 10.

As shown in FIG. 5, the dielectric layer 20 further includes an adhesive layer 40c. The adhesive layer 40c is, for example, in contact with the resistive layer 10. The adhesive layer 40c includes, for example, a rubber adhesive, an acrylic adhesive, a silicone adhesive, or a urethane adhesive. The adhesive layer 40c is disposed, for example, between the first layer 21 and the resistive layer 10.

As shown in FIG. 6, a laminate 1f for a radio wave absorber can also be provided. The laminate 1f for a radio wave absorber is configured in the same manner as the radio wave absorber 1a unless otherwise described. The components of the radio wave absorber 1f that correspond to those of the radio wave absorber 1a are denoted by the same reference characters, and detailed descriptions of such components are omitted.

As shown in FIG. 6, the laminate 1f for a radio wave absorber includes the resistive layer 10 and the dielectric layer 20. The resistive layer 10 is placed on the dielectric layer 20. For example, a radio wave absorber can be produced by attaching the laminate 1f for a radio wave absorber to a member that reflects a radio wave such that the dielectric layer 20 is located between a surface of the member and the resistive layer 10.

### EXAMPLES

Hereinafter, the present invention will be described in more detail by way of examples. However, the present invention is not limited to examples given below. First, evaluation methods for Examples and Comparative Examples will be described.

[Electron Microscopic Observation]

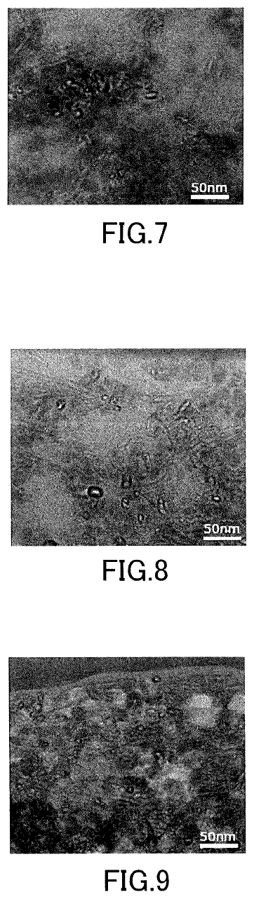

Samples for observation of cross-sections of resistive layers included in resistive-layer-attached films according to Examples and Comparative Examples were produced using a focused ion beam processing and observation system FB2000 manufactured by Hitachi High-Technologies Corporation. Then, the samples for cross-sectional observation were observed using a field emission scanning electron microscope JEM-2800 manufactured by JEOL Ltd. FIGS. 7, 8, and 9 respectively show FE-TEM images of cross-sections of resistive layers of resistive-layer-attached films according to Examples 1, 3, and 5. Additionally, cross-sections of the resistive-layer-attached films according to Examples and Comparative Examples were observed using a scanning electron microscope S-4800 manufactured by Hitachi High-Technologies Corporation, and thicknesses of the resistive layers according to Examples and Comparative Examples were measured. Table 1 shows the results.

[Specific Resistance and Sheet Resistance]

Sheet resistances of the resistive layers of the resistive-layer-attached films according to Examples and Comparative Examples were measured by an eddy current method according to Japanese Industrial Standards JIS Z 2316 using a non-contact resistance measurement apparatus NC-80LINE manufactured by NAPSON CORPORATION. A product of the thickness of each resistive layer measured in the above manner and the sheet resistance thereof measured in the above manner was calculated to determine a specific resistance of the resistive layer.

[Radio Wave Absorption Performance]

By reference to JIS R 1679: 2007, a radio wave with a frequency of 60 to 90 GHz was allowed to be incident using a vector network analyzer manufactured by ANRITSU CORPORATION at an incident angle of 0° on samples according to Examples and Comparative Examples each fixed to a sample holder. A return loss |S| at each frequency was determined by the following equation (1). In the equation (1), P₀ represents the electric power of a transmitted radio wave at the time of incidence of a radio wave on an object to be measured at a given incident angle, and Pᵢ represents the electric power of a received radio wave obtained at the same time. The return losses |S| of the samples were determined assuming that a return loss |S| obtained by allowing a radio wave to be incident at an incident angle of 0° on an aluminum plate, instead of the samples according to Examples and Comparative Examples, fixed to a sample holder was 0 dB. The plate had surface dimensions of 30 cm square and had a thickness of 5 mm. The maximum return loss |S| was determined for each sample. Table 1 shows the results.

S [dB]=10×log |Pᵢ/P₀| Equation (1)

[Tensile Test]

A strip having a length of 50 mm and a width of 10 mm was cut out from each of the resistive-layer-attached films according to Examples and Comparative Examples to produce a specimen for a tensile test. Each specimen was fixed to chucks of a tensile tester. A tensile stress was then applied to the specimen at a tensile rate of 50 μm/sec in the longitudinal direction of the specimen until a strain of the specimen becomes 10%. The initial chuck-to-chuck distance was adjusted to 20 mm. Before and after the tensile test, a probe of a digital multimeter was attached to the specimen, and the electrical resistance R₀ of the resistive layer before the tensile test and the electrical resistance Rₜ of the resistive layer after the tensile test were measured. Table 1 shows values of 100×{(Rₜ/R₀)−1} determined from the measurement results.

[Hot and Humid Environment Test]

Specimens for a hot and humid environment test were produced from samples according to Examples and Comparative Examples. Each specimen was left in an environment having a temperature of 85° C. and a relative humidity of 85% for 24 hours. Before and after the hot and humid environment test, a reflector-attached film was peeled off from each specimen in a glove box at −40° C., and the sheet resistance Rᵢ of the resistive layer before the hot and humid environment test and the sheet resistance R_{H} of the resistive layer before the hot and humid environment test were measured. A non-contact resistance measurement apparatus NC-80MA manufactured by NAPSON CORPORATION was used to measure the sheet resistance Rᵢ and the sheet resistance R_{H}. Table 1 shows values of 100×{(R_{H}/Rᵢ)−1} determined from the measurement results.

### Example 1

A multilayer carbon nanotube (CNT) dispersion MWNT INK manufactured by MEIJO NANO CARBON Co., Ltd. and a urethane-based binder HUX-401 manufactured by ADEKA CORPORATION were mixed, and then stirred at 500 rotations/minute for 5 minutes to prepare a coating solution. Multilayer carbon nanotubes contained in the multilayer CNT dispersion MWNT INK had a diameter of about 10 nm. The amount of the multilayer CNT dispersion MWNT INK added was adjusted so that the multilayer CNT content in solids in the coating solution would be 5 mass %. This multilayer CNT content can be regarded as the multilayer CNT content in a resistive layer. The coating solution was applied to one principal surface of a PET film to form a coating film. After that, the coating film was dried by 90° C. warm air for 3 minutes. Furthermore, the environment of the coating film was maintained at 120° C. for 15 minutes to dry the coating film. A resistive layer according to Example 1 was formed in this manner. A resistive-layer-attached film according to Example 1 was produced in this manner. Coating film formation conditions were adjusted so that the resistive layer would have a thickness of 31 μm. Next, an acrylic resin having a relative permittivity of 2.6 was shaped to have a thickness of 560 μm to obtain an acrylic resin layer A. Separately, a reflector-attached film in which an aluminum layer was disposed between a pair of PET layers was obtained. One PET layer of the reflector-attached film had a thickness of 25 μm, and the other PET layer had a thickness of 9 μm. The aluminum layer of the reflector-attached film had a thickness of 7 μm. The resistive-layer-attached film according to Example 1 was placed on the acrylic resin layer A such that the resistive layer of the resistive-layer-attached film according to Example 1 was in contact with one principal surface of the acrylic resin layer A. Moreover, the reflector-attached film was placed on the acrylic resin layer A such that the 25 μm-thick PET layer of the reflector-attached film was in contact with the other principal surface of the acrylic resin layer A. A sample according to Example 1 was obtained in this manner.

### Example 2

A resistive-layer-attached film according to Example 2 was produced in the same manner as in Example 1, except for the following points. In preparation of the coating solution, the amount of the multilayer CNT dispersion MWNT INK added was adjusted so that the multilayer CNT content in solids in the coating solution would be 9 mass %. Additionally, the coating film formation conditions were adjusted so that the resistive layer would have a thickness of 12 μm. A sample according to Example 2 was produced in the same manner as in Example 1, except that the resistive-layer-attached film according to Example 2 was used instead of the resistive-layer-attached film according to Example 1.

### Example 3

A resistive-layer-attached film according to Example 3 was produced in the same manner as in Example 1, except for the following points. In preparation of the coating solution, the amount of the multilayer CNT dispersion MWNT INK added was adjusted so that the multilayer CNT content in solids in the coating solution would be 13 mass %. Additionally, the coating film formation conditions were adjusted so that the resistive layer would have a thickness of 6.5 μm. A sample according to Example 3 was produced in the same manner as in Example 1, except that the resistive-layer-attached film according to Example 3 was used instead of the resistive-layer-attached film according to Example 1.

### Example 4

A resistive-layer-attached film according to Example 4 was produced in the same manner as in Example 1, except for the following points. In preparation of the coating solution, the amount of the multilayer CNT dispersion MWNT INK added was adjusted so that the multilayer CNT content in solids in the coating solution would be 49 mass %. Additionally, the coating film formation conditions were adjusted so that the resistive layer would have a thickness of 2 μm. A sample according to Example 4 was produced in the same manner as in Example 1, except that the resistive-layer-attached film according to Example 4 was used instead of the resistive-layer-attached film according to Example 1.

### Example 5

A resistive-layer-attached film according to Example 5 was produced in the same manner as in Example 1, except for the following points. In preparation of the coating solution, the amount of the multilayer CNT dispersion MWNT INK added was adjusted so that the multilayer CNT content in solids in the coating solution would be 65 mass %. Additionally, the coating film formation conditions were adjusted so that the resistive layer would have a thickness of 1 μm. A sample according to Example 5 was produced in the same manner as in Example 1, except that the resistive-layer-attached film according to Example 5 was used instead of the resistive-layer-attached film according to Example 1.

### Comparative Example 1

A resistive-layer-attached film according to Comparative Example 1 was produced in the same manner as in Example 1, except for the following points. In preparation of the coating solution, the amount of the multilayer CNT dispersion MWNT INK added was adjusted so that the multilayer CNT content in solids in the coating solution would be 1 mass %. Additionally, the coating film formation conditions were adjusted so that the resistive layer would have a thickness of 61 μm. A sample according to Comparative Example 1 was produced in the same manner as in Example 1, except that the resistive-layer-attached film according to Comparative Example 1 was used instead of the resistive-layer-attached film according to Example 1.

### Comparative Example 2

A resistive-layer-attached film according to Comparative Example 2 was produced in the same manner as in Example 1, except for the following points. In preparation of the coating solution, a single-layer CNT dispersion TB002M manufactured by KJ SPECIALTY PAPER Co., Ltd. was used instead of the multilayer CNT dispersion MWNT INK, and the coating film formation conditions were adjusted so that the resistive layer would have a thickness of less than 0.2 μm. A sample according to Comparative Example 2 was produced in the same manner as in Example 1, except that the resistive-layer-attached film according to Comparative Example 2 was used instead of the resistive-layer-attached film according to Example 1.

The samples according to Examples and Comparative Examples each have a given maximum return loss |S| and given radio wave absorption performance, as shown in Table 1. For the resistive layers according to Examples, the values of 100×{(Rₜ/R₀)−1} and 100×{(R_{H}/Rᵢ)−1} are small. This is interpreted as meaning that the resistive layers according to Examples have a high tensile resistance and a high durability in the hot and humid environment. On the other hand, the value of 100×{(Rₜ/R₀)−1} is large in Comparative Example 1; it is hard to say that the resistive layer according to Comparative Example 1 has a high tensile resistance. The value of 100×{(R_{H}/Rᵢ)−1} is large in Comparative Example 2; it is hard to say that the resistive layer according to Comparative Example 2 has a high durability in the hot and humid environment.

TABLE 1

| | Resistive layer | | | | | | Hot and | Radio wave |
|---|---|---|---|---|---|---|---|---|
| | | | | | CNT content | | humid | absorption |
| | | | | | in solids in | | environment | performance |
| | | Specific | Sheet | | coating | Tensile test | test | Maximum |
| | Type of | resistance | resistance | Thickness | solution | 100 × {(Rₜ/ | 100 × {(R_{H}/ | return loss \|S\| |
| | CNT | [Ω · cm] | [Ω/□] | [μm] | [mass %] | R₀) − 1} | Rᵢ) − 1} | [dB] |
| Example 1 | Multilayer | 1.11 | 357 | 31 | 5 | 0 | 1 | 24.1 |
| | CNT | | | | | | | |
| Example 2 | Multilayer | 0.57 | 471 | 12 | 9 | 1 | 0 | 21.2 |
| | CNT | | | | | | | |
| Example 3 | Multilayer | 0.26 | 395 | 6.5 | 13 | 0 | 1 | 27.8 |
| | CNT | | | | | | | |
| Example 4 | Multilayer | 0.08 | 403 | 2 | 49 | 0 | 1 | 36.5 |
| | CNT | | | | | | | |
| Example 5 | Multilayer | 0.03 | 258 | 1 | 65 | 0 | 1 | 19.2 |
| | CNT | | | | | | | |
| Comparative | Multilayer | 2.34 | 384 | 61 | 1 | 27 | 1 | 23.6 |
| Example 1 | CNT | | | | | | | |
| Comparative | Single- | Less | 384 | Less | — | 1 | 432 | 30.1 |
| Example 2 | layer CNT | than 0.01 | | than 0.2 | | | | |

1. A radio wave absorber comprising:
a resistive layer including multilayer carbon nanotubes and having a specific resistance of 1.5 Ω·cm or less;
a reflector that reflects a radio wave; and
a dielectric layer disposed between the resistive layer and the reflector in a thickness direction of the resistive layer.

2. The radio wave absorber according to claim 1, wherein the multilayer carbon nanotube has a diameter of 70 nm or less.

3. The radio wave absorber according to claim 1, wherein
the resistive layer includes a binder binding the multilayer carbon nanotubes to each other, and
the binder includes at least one selected from the group consisting of a polyurethane, a polyacrylate, an epoxy resin, and a polyester.

4. The radio wave absorber according to claim 1, wherein the resistive layer is free of an aliphatic cellulose ester.

5. The radio wave absorber according to claim 1, wherein an electrical resistance Rt of the resistive layer after a tensile test in which a tensile stress is applied to the resistive layer in a direction perpendicular to the thickness direction of the resistive layer to cause a 10% strain and an electrical resistance R0 of the resistive layer before the tensile test satisfy a relation 100×{(Rt/R0)−1}≤15.

6. The radio wave absorber according to claim 1, further comprising a supporting layer including an organic polymer, the supporting layer supporting the resistive layer.

7. The radio wave absorber according to claim 1, wherein a content of the multilayer carbon nanotubes in the resistive layer is 3% or more on a mass basis.

8. A laminate for a radio wave absorber, the laminate comprising:
a resistive layer including multilayer carbon nanotubes and having a specific resistance of 1.5 Ω·cm or less; and
a dielectric layer, wherein
the resistive layer is placed on the dielectric layer.
